(19) United States
(12) Patent Application Publication
(10) Pub. No.: US 2026/0165008 A1
(43) Pub. Date: Jun. 11, 2026

(54) DISPLAY PANEL AND ELECTRONIC APPARATUS INCLUDING THE SAME

(71) Applicant: Samsung Display Co., Ltd., Yongin-Si (KR)

(72) Inventors: SOOYOUN KIM, Yongin-si (KR); EUNJIN KWAK, Yongin-si (KR); GEE-BUM KIM, Yongin-si (KR); HYUNHO KIM, Yongin-si (KR)

(21) Appl. No.: 19/366,744

(22) Filed: Oct. 23, 2025

(30) Foreign Application Priority Data
Dec. 5, 2024 (KR) 10-2024-0179100

(51) Int. Cl. H10K 59/80; H10K 59/122

(52) U.S. Cl. CPC H10K 59/879; H10K 59/122; H10K 59/80518

(57) ABSTRACT

A display panel includes a first insulation layer on a base layer and including a first opening, a reflection layer on the first insulation layer, a second insulation layer on the reflection layer, a pixel-defining film on the second insulation layer and including a second opening, a first electrode on the second insulation layer, a light-emitting layer disposed in the second opening of the pixel-defining film and overlapping the first electrode, and a second electrode on the light-emitting layer. The first electrode may include a first part disposed in the first opening and arranged perpendicular to a thickness direction, and a second part extending from the first part and disposed on an inner surface of the first insulation layer which defines the first opening. The second part of the first electrode may be inclined at a first acute angle of less than about 50° with respect to a plane.

### CROSS-REFERENCE TO RELATED APPLICATIONS

This application claims priority under 35 U.S.C. § 119 to Korean Patent Application No. 10-2024-0179100, filed on Dec. 5, 2024, the entire contents of which are hereby incorporated by reference.

### BACKGROUND

The present disclosure herein relates to a display panel including a reflection layer, and an electronic apparatus including the same.

As the information-oriented society advances, the demand for a display device for displaying an image is increasing in various forms. For instance, a display device is applied to various electronic apparatuses such as a smartphone, a digital camera, a laptop computer, a navigation unit, and a smart television. A display device may include a display panel for generating an image, and the display panel may be an organic light-emitting display panel. The organic light-emitting display panel includes so called self-luminous light-emitting element which display images by causing a light-emitting material of a light-emitting layer to emit light through the recombination, in the light-emitting layer, of holes and electrons injected from a first electrode and a second electrode. A study is being conducted to improve the display quality of a display device in consideration of the various usage environments of the display device.

### SUMMARY

The present disclosure provides a display panel exhibiting excellent display quality and an electronic apparatus including the same.

According to an embodiment of the inventive concept, a display panel includes a base layer, a first insulation layer disposed on the base layer and including a first opening, a reflection layer disposed on the first insulation layer, a second insulation layer disposed on the reflection layer, a pixel-defining film disposed on the second insulation layer and including a second opening, a first electrode disposed on the second insulation layer, a light-emitting layer disposed on the first electrode and overlapping the first electrode in the second opening of the pixel-defining film, and a second electrode disposed on the light-emitting layer. The first electrode includes a first part disposed in the first opening and arranged perpendicular to a thickness direction, and a second part extending from the first part and disposed on an inner surface of the first insulation layer which defines the first opening. The second part of the first electrode is inclined at a first acute angle of less than about 50° with respect to a plane perpendicular to the thickness direction.

In an embodiment, the first electrode may include a transmissive electrode or a transflective electrode.

In an embodiment, the reflection layer may include a first part disposed in the first opening and overlapping the first part of the first electrode, and a second part extending from the first part of the reflection layer and disposed on the inner surface of the first insulation layer. The second part of the reflection layer may be inclined at a second acute angle of less than about 50° with respect to the plane.

In an embodiment, the second acute angle may satisfy the following Equation 1:

$${A}_{2} \leq ( 50 + {A}_{1} ) / 2. \qquad [ Expression 1 ]$$

Wherein, in the Equation 1, A₁ may represent the first acute angle and A₂ may represent the second acute angle.

In an embodiment, the first part of the reflection layer may extend in a first direction perpendicular to the thickness direction.

In an embodiment, the first part of the reflection layer may be inclined at a third acute angle of less than about 25° with respect to the plane.

In an embodiment, the display panel may further include a third insulation layer disposed between the base layer and the first insulation layer. An upper surface of the third insulation layer disposed under the first insulation layer may not be flat.

In an embodiment, in a first direction perpendicular to the thickness direction, the second insulation layer may be disposed between the second part of the reflection layer and the second part of the first electrode.

In an embodiment, the second part of the reflection layer may not overlap the first part of the first electrode.

In an embodiment, the reflection layer may be provided in plurality, and the plurality of reflection layers may be spaced apart from each other in a first direction perpendicular to the thickness direction.

In an embodiment, the reflection layer may include at least one of Ag, Mg, Cu, Al, Pt, Pd, Au, Ni, Nd, Ir, Cr, Li, Ca, Mo, Ti, or W.

In an embodiment, the first opening may overlap the second opening.

In an embodiment, each of the first insulation layer and the second insulation layer may include an organic material.

In an embodiment, the display panel may be foldable with respect to a folding axis.

According to an embodiment of the inventive concept, an electronic apparatus includes a display panel and a housing for accommodating the display panel. The display panel includes a base layer, a first insulation layer disposed on the base layer and including a first opening, a reflection layer disposed on the first insulation layer, a second insulation layer disposed on the reflection layer, a pixel-defining film disposed on the second insulation layer and including a second opening, a first electrode disposed on the second insulation layer, a light-emitting layer disposed on the first electrode and overlapping the first electrode in the second opening of the pixel-defining film, and a second electrode disposed on the light-emitting layer. The first electrode includes a first part disposed in the first opening and arranged perpendicular to a thickness direction, and a second part extending from the first part and disposed on an inner surface of the first insulation layer which defines the first opening. The second part of the first electrode is inclined at a first acute angle of less than about 50° with respect to a plane perpendicular to the thickness direction.

In an embodiment, the first electrode may include a transmissive electrode or a transflective electrode.

In an embodiment, the reflection layer may include a first part disposed in the first opening and overlapping the first part of the first electrode, and a second part extending from the first part of the reflection layer and disposed on the inner surface of the first insulation layer. The second part of the reflection layer may be inclined at a second acute angle of less than about 50° with respect to the plane.

In an embodiment, the first part of the reflection layer may extend in a first direction perpendicular to the thickness direction.

In an embodiment, the first part of the reflection layer may be inclined at a third acute angle of less than about 25° with respect to the plane.

In an embodiment, the second part of the reflection layer may not overlap the first part of the first electrode.

### BRIEF DESCRIPTION OF THE DRAWINGS

The accompanying drawings are included to provide a further understanding of the inventive concept, and illustrate an embodiment of the inventive concept and, together with the following description, to explain features of the inventive concept.

FIG. 1A is a perspective view illustrating an electronic apparatus according to an embodiment.

FIG. 1B is a perspective view illustrating an electronic apparatus according to an embodiment.

FIG. 2 is an exploded perspective view illustrating an electronic apparatus according to an embodiment.

FIG. 3 is a block diagram of an electronic apparatus according to an embodiment.

FIG. 4 is a cross-sectional view illustrating a portion taken along line a I-I′ in

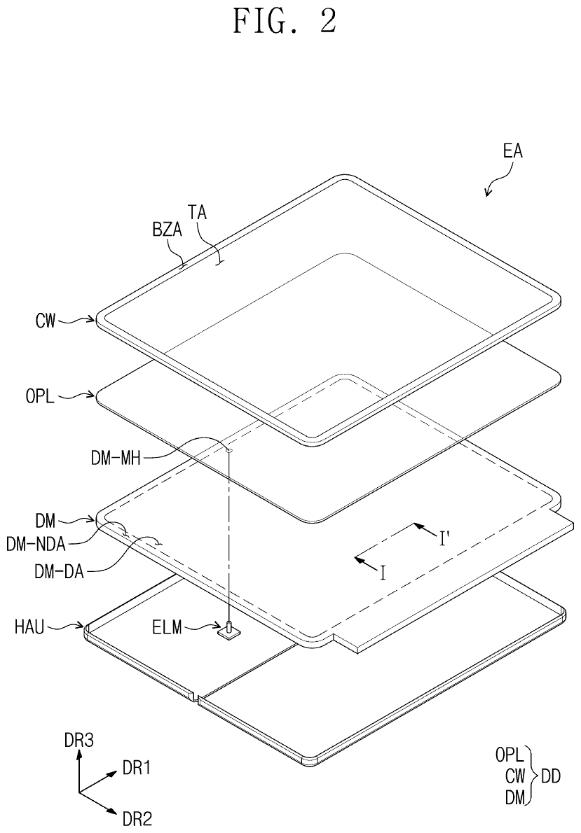

FIG. 2.

FIG. 5 is a plan view illustrating a portion of an electronic apparatus according to an embodiment.

FIG. 6A is a cross-sectional view illustrating a display panel according to an embodiment.

FIG. 6B is an enlarged cross-sectional view illustrating a region XX′ in FIG. 6A.

FIG. 6C is a cross-sectional view illustrating a portion of a display panel according to an embodiment.

FIG. 6D is a cross-sectional view illustrating a portion of a display panel according to an embodiment.

FIG. 7A is a cross-sectional view illustrating a display panel according to an embodiment.

FIG. 7B is an enlarged cross-sectional view illustrating a region YY′ in FIG. 7A.

FIG. 8 is a graph showing brightness versus angle in a display panel according to Comparative Example and Examples.

FIG. 9 is a cross-sectional view illustrating a portion of a display panel according to an embodiment.

FIG. 10 is a perspective view illustrating an electronic apparatus according to an embodiment.

FIG. 11A is a perspective view illustrating an electronic apparatus according to an embodiment.

FIG. 11B is an exploded perspective view illustrating an electronic apparatus according to an embodiment.

### DETAILED DESCRIPTION

It is noted that, although the inventive concept may include various modifications and changes in various forms, specific embodiments will be described in detail hereinafter with reference to the drawings. However, this is not intended to limit the inventive concept to a specific embodiments disclosed in the present disclosure, but it should be understood that the inventive concept includes all changes, equivalents, and substitutes unless they do not depart from the spirit and scope of the inventive concept.

In this specification, it will be understood that when an element (or a region, a layer, a portion, or the like) is referred to as being “on”, “connected to” or “coupled to” another element, it may be directly disposed on, connected to or coupled to the other element, or indirectly on, connected to or coupled to other element with an intervening element disposed therebetween.

Like reference numerals or symbols refer to like elements throughout this specification. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be referred to as a second element without departing from the scope of the inventive concept. Similarly, a second element could also be referred to as a first element. In this specification, the singular expressions “a”, “an” and “the” are intended to include the plural forms as well, unless the context clearly indicates otherwise.

In addition, the terms, such as “below”, “under”, “on the lower side”, “above”, “over”, “on the upper side”, or the like, may be used to describe the spatial relation between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless defined otherwise, all terms (including technical and scientific terms) used herein have the same meaning as commonly understood by one of ordinary skill in the art to which the inventive concept pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display panel and an electronic apparatus including the display panel, according to an embodiment of the inventive concept, will be described with reference to the drawings.

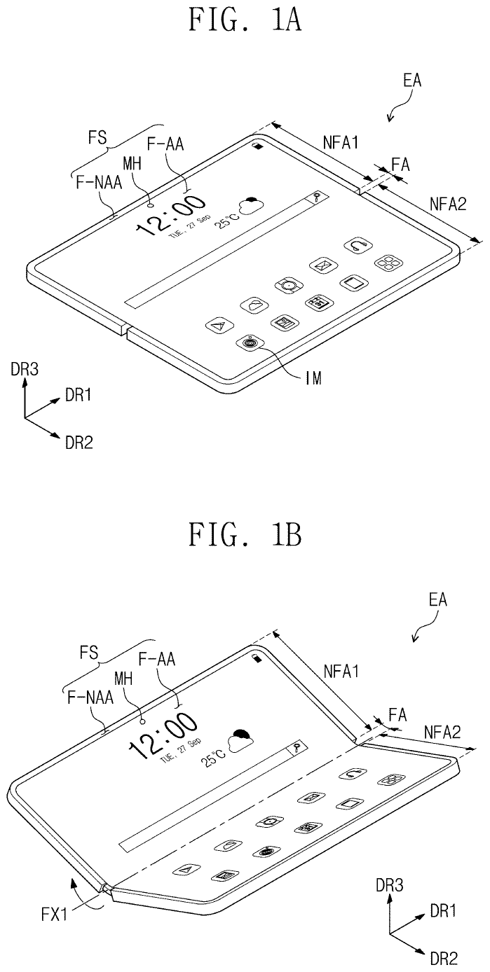

FIG. 1A is a perspective view of an electronic apparatus EA, according to an embodiment, in an unfolded state.

The electronic apparatus EA according to an embodiment may be an apparatus activated in response to an electrical signal. For example, the electronic apparatus EA may be a television, a monitor, an outdoor billboard, a personal computer, a laptop computer, a tablet computer, a smartphone, a car navigation unit, a game console, a camera, or a wearable apparatus, but the embodiment of the inventive concept is not limited thereto. For ease of the description, the electronic apparatus EA of the inventive concept, hereinafter, is exemplified as a tablet computer, as illustrated in FIG. 1A, etc.

The electronic apparatus EA may include a display surface FS defined by a first direction axis DR1 and a second direction axis DR2 crossing the first direction axis DR1. The electronic apparatus EA may provide an image IM to a user through the display surface FS. The electronic apparatus EA may display the image IM toward a third direction axis DR3, which is perpendicular to each of the first direction axis DR1 and the second direction axis DR2, on the display surface FS. The image IM that the electronic apparatus EA displays may include a dynamic image and/or a static image.

In this specification, the first direction axis DR1 and the second direction axis DR2 are orthogonal to each other, and the third direction axis DR3 may be a normal direction to a plane defined by the first direction axis DR1 and the second direction axis DR2. A thickness direction of the electronic apparatus EA may be a direction parallel to the third direction axis DR3. The thickness direction of the electronic apparatus EA and the third direction axis DR3 may be indicated by the same reference numeral or symbol. A front surface (or an upper surface) and a rear surface (or a lower surface) may be opposed to each other in the third direction axis DR3, and a normal direction to each of the front surface (or the upper surface) and the rear surface (or the lower surface) may be parallel to the third direction axis DR3. The front surface (or the upper surface) indicates a surface adjacent to the display surface FS and the rear surface (or the lower surface) indicates a surface spaced apart from the display surface FS in the third direction axis DR3. An upper side (or an upper part) indicates a direction closer to the display surface FS and a lower side (or a lower part) indicates a direction farther away from the display surface FS.

A cross section indicates a surface parallel to the thickness direction DR3, and a plane indicates a surface perpendicular to the thickness direction DR3. The plane indicates a surface parallel to the surface defined by the first direction axis DR1 and the second direction axis DR2.

Directions indicated by the first to third direction axes DR1, DR2, and DR3 described herein are relative concepts and may thus be changed to other directions. Also, the directions indicated by the first to third direction axes DR1, DR2, and DR3 may be described as first to third directions, and the same reference numerals or symbols may be used.

In this specification, one component overlapping another component in a plan view indicates that the components overlap with each other in the thickness direction DR3. One component overlapping another component is not limited to the case where the components have the same area and the same shape, and indicates even the case where the components have different areas and/or different shapes.

The electronic apparatus EA may detect an external input applied from the outside. The external input may include various types of inputs provided from the outside of the electronic apparatus EA. For example, the external input may include not only a touch by a portion of a body such as a user's hand, but also an external input applied proximate to or adjacent to, within a certain distance, the electronic apparatus EA (for example, hovering). In addition, the external input may have various types such as force, pressure, temperature, light, or the like.

In the electronic apparatus EA, the display surface FS may include a display region F-AA, a non-display region F-NAA, and a sub region MH. The display region F-AA may be a region activated in response to an electrical signal. The display region F-AA may be a region which displays the image IM and which is capable of detecting various types of external inputs.

The non-display region F-NAA may be adjacent to the display region F-AA. A light transmittance of the non-display region F-NAA may be lower than a light transmittance of the display region F-AA. The non-display region F-NAA may not be optically transparent and have a color. The non-display region F-NAA may surround the display region F-AA. Accordingly, the shape of the display region F-AA may be substantially defined by the non-display region F-NAA. However, this is an example, and the non-display region F-NAA may be disposed adjacent to only one side of the display region F-AA, or be omitted.

The sub region MH may detect an external subject received through the display surface FS or provide, to the outside, a sound such as voice through the display surface FS. A light signal such as visible light or infrared light may pass through the sub region MH.

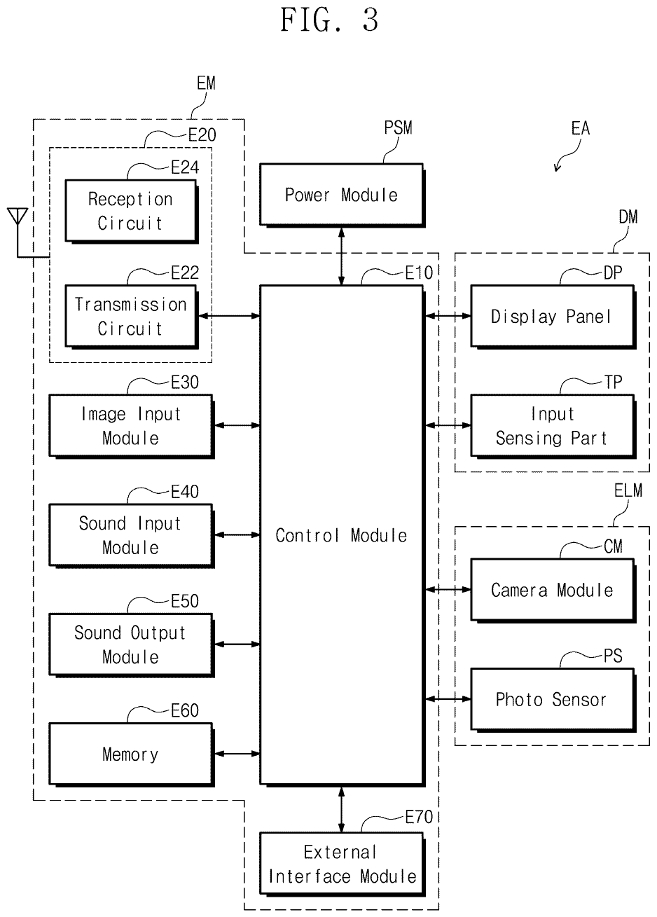

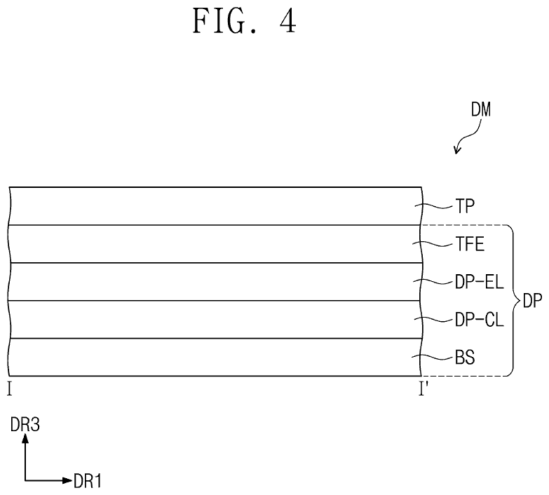

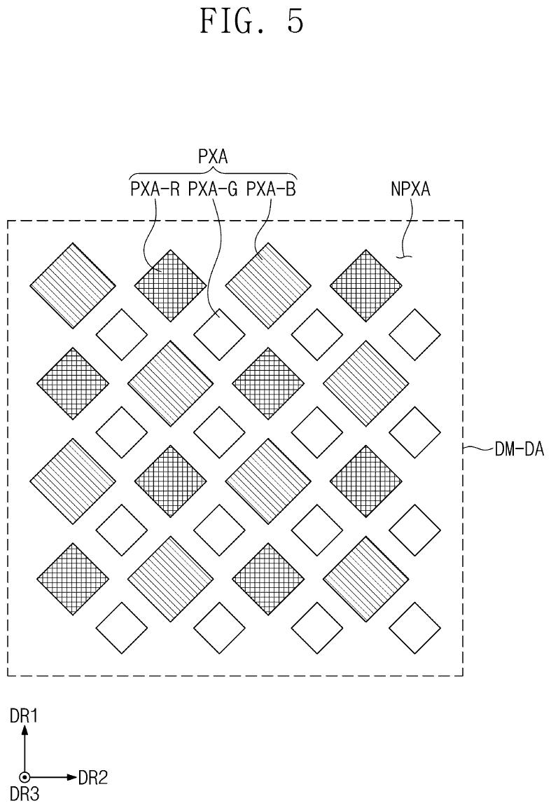

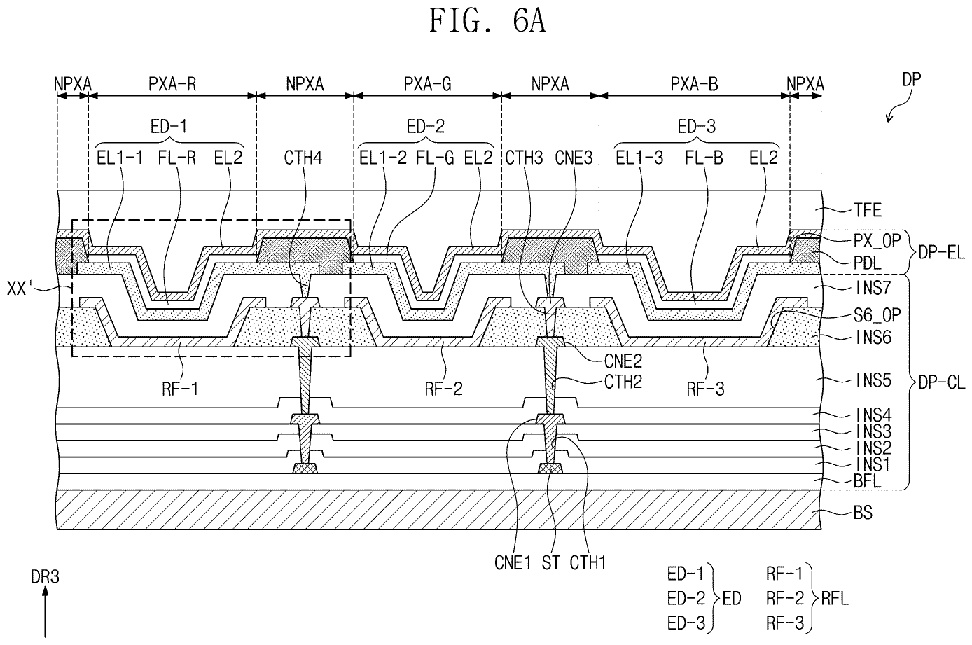

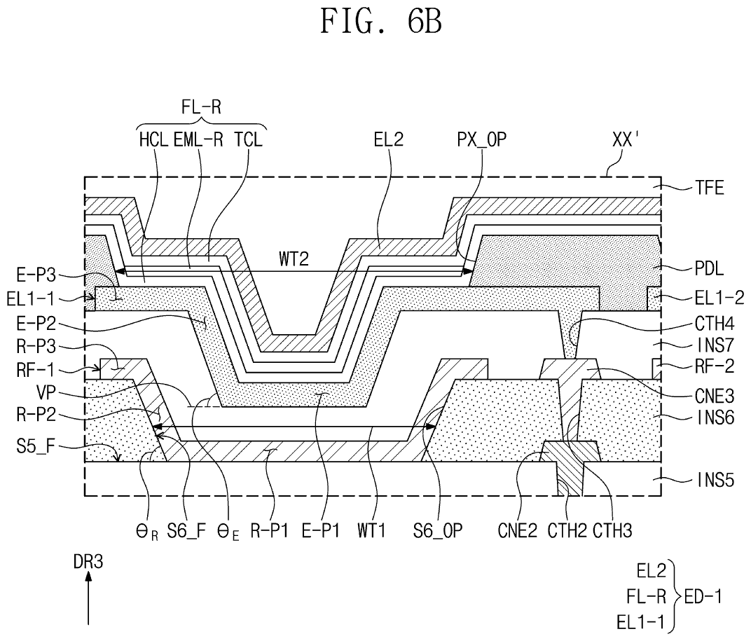

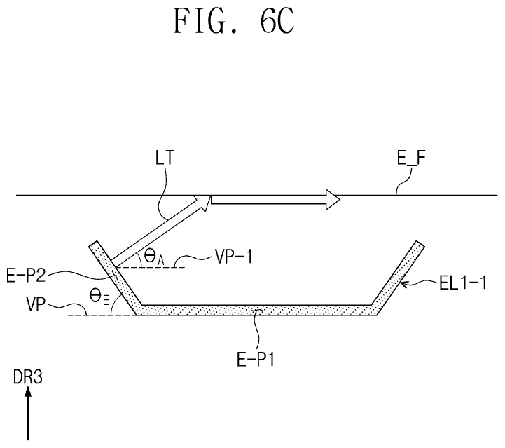

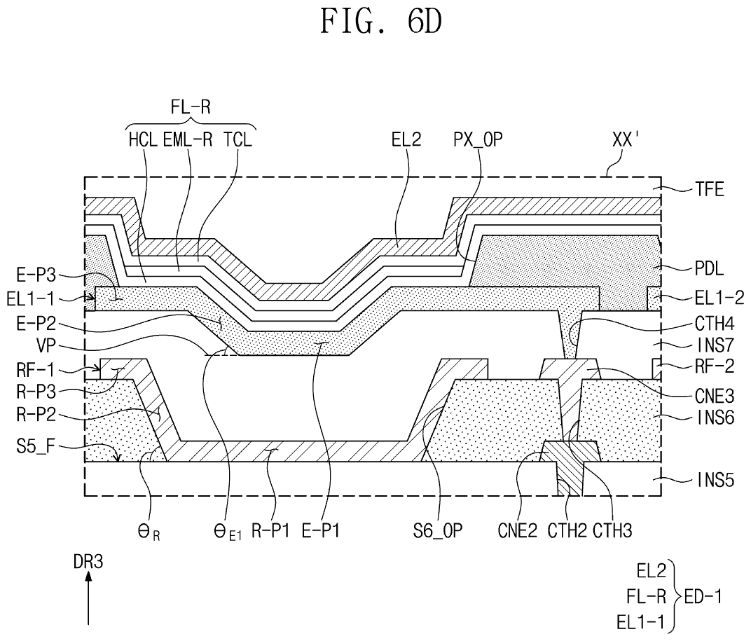

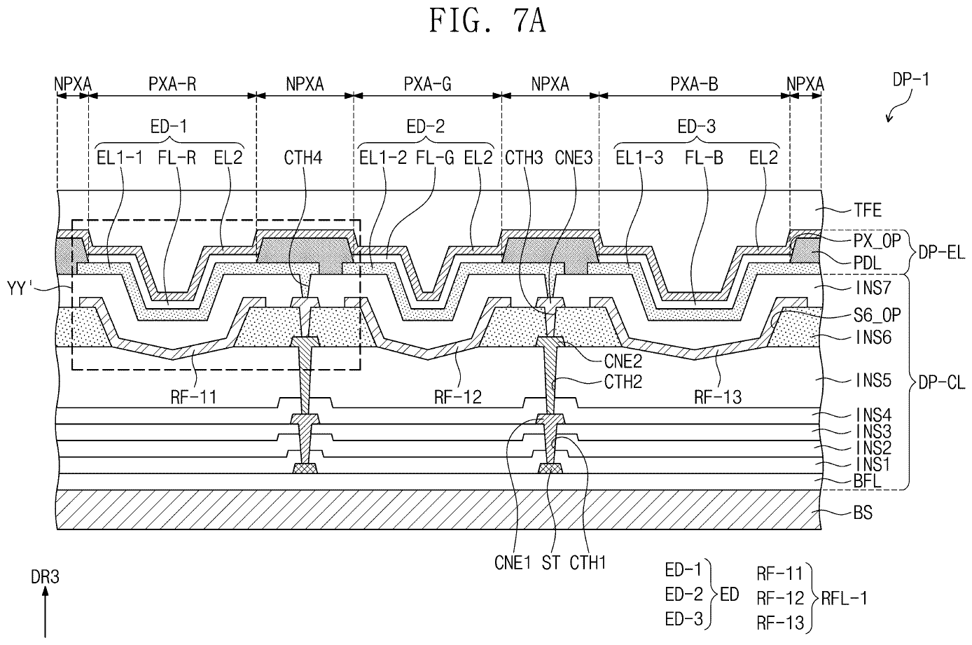

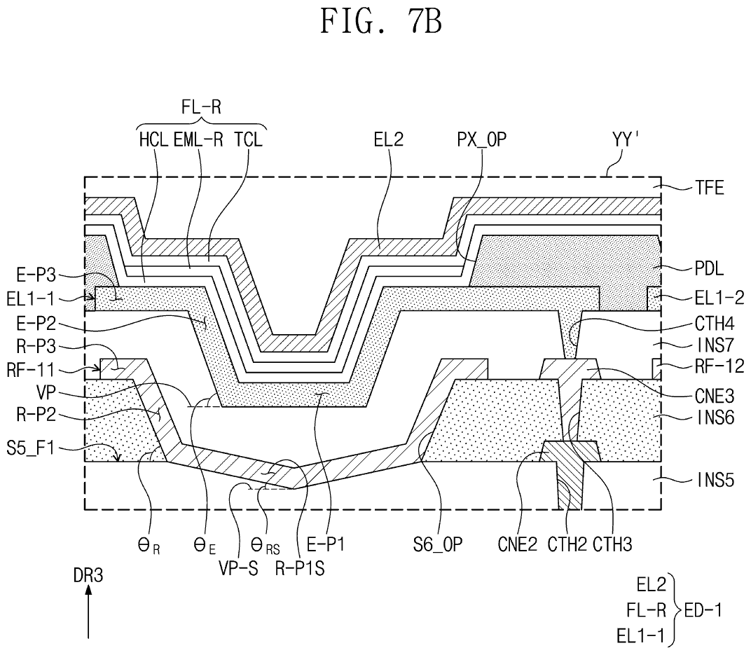

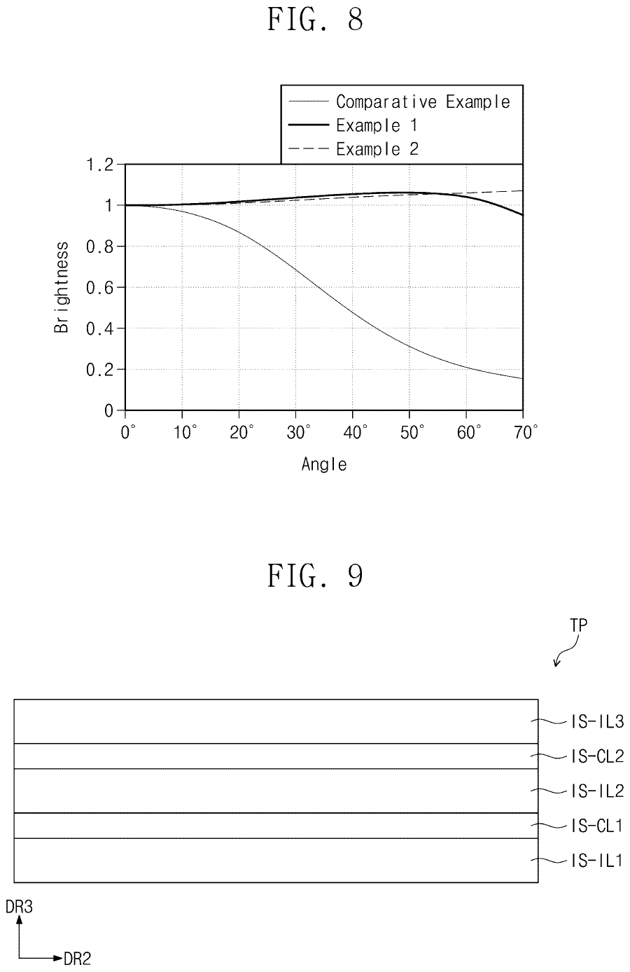

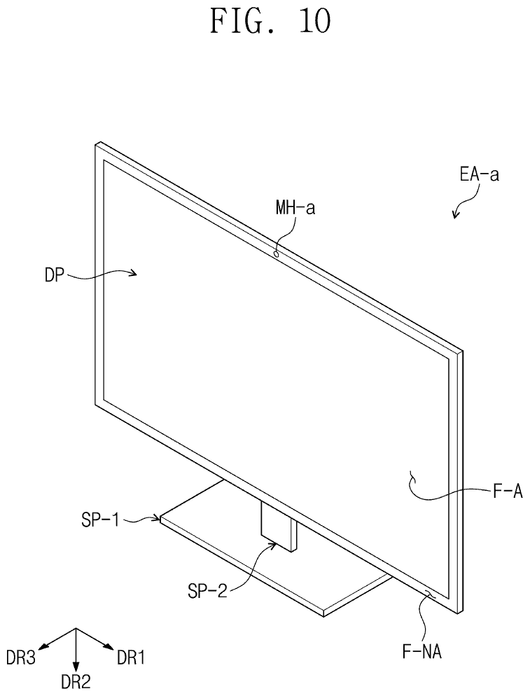

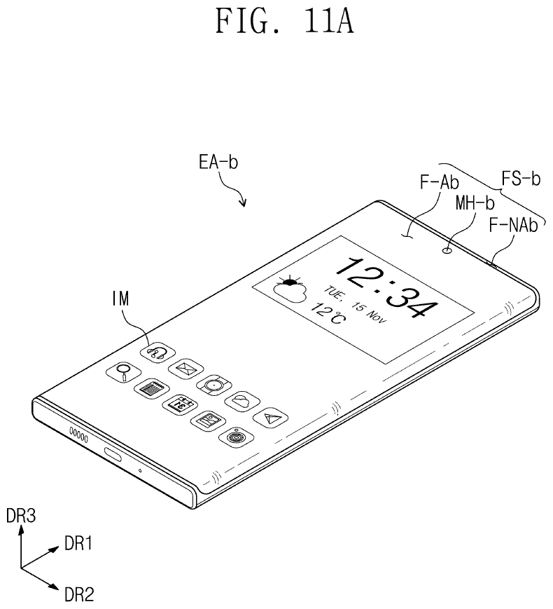

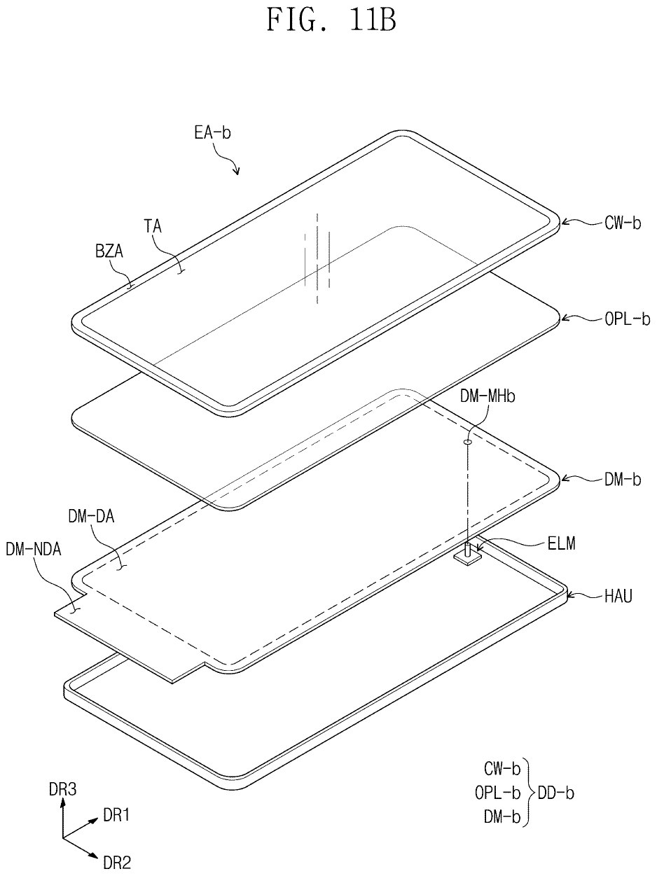

A second electronic module ELM (see FIGS. 3 and 4) may be disposed in a region corresponding to the sub region MH. For example, the second electronic module ELM (see FIGS. 3 and 4) may include at least one among a camera, a speaker, a light detecting sensor, and a heat detecting sensor. The electronic apparatus EA may include the second electronic module ELM (see FIGS. 3 and 4) which captures external images using visible light passing through the sub region MH or determines proximity of an external object using infrared light. The second electronic module ELM (see FIGS. 3 and 4) may include a plurality of components. For example, the second electronic module ELM (see FIGS. 3 and 4) may include at least two components among the camera, the speaker, the light detecting sensor, the heat detecting sensor, or others.

The sub region MH may be disposed within the display region F-AA. However, this is an example, and the embodiment is not limited thereto. For instance, the sub region MH may be surrounded by the non-display region F-NAA or surrounded by both the display region F-AA and the non-display region F-NAA. FIG. 1A, etc. illustrates one sub region MH, but the electronic apparatus EA may include a plurality of the sub regions MH.

The electronic apparatus EA according to an embodiment may be flexible. The term “flexible” may indicate a bendable property, and may include all structures spanning from a structure which is completely foldable to a structure which is bendable to the level of several nanometers. For instance, the electronic apparatus EA may be a foldable apparatus. However, the embodiment of the electronic apparatus EA is not limited thereto. For example, the electronic apparatus EA may be a rigid apparatus.

The electronic apparatus EA according to an embodiment may include at least one folding region FA and a plurality of non-folding regions NFA1 and NFA2 extending from the folding region FA. For example, a first non-folding region NFA1, the folding region FA, and a second non-folding region NFA2 may be defined along the second direction DR2. The electronic apparatus EA according to an embodiment may include the first non-folding region NFA1 and the second non-folding region NFA2 spaced apart from each other in the second direction DR2. In the electronic apparatus EA, the folding region FA may be disposed between the first non-folding region NFA1 and the second non-folding region NFA2 along the second direction DR2. For example, the first non-folding region NFA1 may be adjacent to one side of the folding region FA along the second direction DR2, and the second non-folding region NFA2 may be adjacent to the other side of the folding region FA along the second direction DR2.

FIG. 1A, etc., illustrate an embodiment of the electronic apparatus EA which includes one folding region FA, but the embodiment is not limited thereto and a plurality of folding regions may be defined in the electronic apparatus EA. For example, the electronic apparatus EA according to an embodiment may include two or more folding regions and three or more non-folding regions. The respective non-folding regions may be disposed between adjacent folding regions.

FIG. 1B is a perspective view illustrating a folding operation of the electronic apparatus EA according to an embodiment. Referring to FIG. 1B, the electronic apparatus EA according to an embodiment may be folded with respect to a folding axis FX1 extending in the first direction DR1. When the electronic apparatus EA is in a folded state, the folding region FA may have a curvature and a radius of curvature. The electronic apparatus EA may be folded with respect to the folding axis FX1 and changed to an in-folded state so that the first non-folding region NFA1 and the second non-folding region NFA2 face each other and the display surface FS is not exposed to the outside. Although not illustrated, the electronic apparatus EA may be changed to an out-folded state so that the display surface FS is exposed to the outside. The electronic apparatus EA may be configured so that the in-folding or out-folding operation may be repeatedly performed from the unfolded state, but an embodiment of the inventive concept is not limited thereto.

FIG. 1B illustrates an example in which the electronic apparatus is folded with respect to one folding axis FX1, but the number of folding axes and the resulting number of non-folding regions in the electronic apparatus EA are not limited thereto. For example, the electronic apparatus EA may be folded with respect to a plurality of folding axes and the electronic apparatus may be folded such that portions of the display surface FS face each other. In addition, although the folding axis FX1 is illustrated as parallel to a long side of the electronic apparatus EA, the embodiment is not limited thereto, and the folding axis FX1 may be parallel to a short side of the electronic apparatus EA.

The first non-folding region NFA1 and the second non-folding region NFA2 in the electronic apparatus EA may be defined, in a folded state as illustrated in FIG. 1B, as a portion having the display surface FS which is parallel to a plane defined by the first direction axis DR1 and the second direction axis DR2, and the folding region FA may be defined as a region between the first non-folding region NFA1 and the second non-folding region NFA2. The folding region FA may include, in a folded state, a curved part that is bent so as to have a curvature.

FIG. 2 is an exploded perspective view of an electronic apparatus EA according to an embodiment. Referring to FIG. 2, the electronic apparatus EA may include a second electronic module ELM, a display device DD, and a housing HAU. The display device DD may include a display module DM and a window member CW disposed on the display module DM. The display device DD may have a module region DM-MH, and the second electronic module ELM may be disposed in a region corresponding to the module region DM-MH.

In the electronic apparatus EA, the window member CW and the housing HAU may be coupled together to form an exterior of the electronic apparatus EA. The housing HAU may be disposed under the display module DM. The housing HAU may include a material having a relatively high rigidity. For example, the housing HAU may include a plurality of frames and/or plates containing glass, plastic, or metal. The housing HAU may provide an accommodation space. The second electronic module ELM, the display module DM, and the like may be accommodated inside the accommodation space of the housing HAU and protected from an external impact.

The display module DM may be activated in response to an electrical signal. The display module DM may be activated to display the image IM (see FIG. 1A) in the display region F-AA (see FIG. 1A) of the electronic apparatus EA. An active region DM-DA, a peripheral region DM-NDA, and the module region DM-MH may be defined in the display module DM. The module region DM-MH may be defined in a display panel DP (see FIG. 4) included in the display module DM.

The active region DM-DA may be a region activated in response to an electrical signal. Pixels may be disposed in the active region DM-DA. A pixel may include a transistor and a light-emitting element ED (see FIG. 6A). The peripheral region DM-NDA may be a region positioned adjacent to at least one side of the active region DM-DA. Circuits or lines for driving the active region DM-DA may be disposed in the peripheral region DM-NDA.

The module region DM-MH may correspond to the sub region MH illustrated in FIG. 1A. Light such as visible light or infrared light may pass through the module region DM-MH. The module region DM-MH may be disposed within the active region DM-DA. However, the embodiment is not limited thereto. For example, the module region DM-MH may be surrounded by the peripheral region DM-NDA, or surrounded by both the active region DM-DA and the peripheral region DM-NDA.

The second electronic module ELM may be an electronic component which outputs or receives the light including the visible light, the infrared light or others. For example, the second electronic module ELM may include a camera module CM (see FIG. 3) and a photo sensor PS (see FIG. 3). The camera module CM (see FIG. 3) may capture external images through the module region DM-MH. The photo sensor PS (see FIG. 3) may receive incident light, and the incident light may be infrared light. The photo sensor PS (see FIG. 3) may receive infrared light reflected from an external object and detect an approach of the external object. The photo sensor PS (see FIG. 3) may perform the function of a proximity sensor.

The window member CW may be a base substrate which includes a glass substrate or a plastic substrate. For example, the window member CW may include a base substrate including at least one of polyimide, polyacrylate, polymethylmethacrylate, polycarbonate, polyethylenenaphthalate, polyvinylidene chloride, polyvinylidene difluoride, polystyrene, or ethylene vinylalcohol copolymer. However, this is an example, and the embodiment is not limited thereto.

The window member CW may include a transmission region TA and a bezel region BZA. The transmission region TA may overlap at least a portion of the active region DM-DA of the display module DM. The transmission region TA may be an optically transparent region. The image IM (see FIG. 1A) may be provided to the users through the transmission region TA.

The bezel region BZA may have a relatively low light transmittance than the transmission region TA. The bezel region BZA may define the shape of the transmission region TA. The bezel region BZA may be adjacent to the transmission region TA and surround at least one side of the transmission region TA.

The bezel region BZA may not be optically transparent and have a color. The bezel region BZA may cover the peripheral region DM-NDA of the display module DM and block the peripheral region DM-NDA from being visible from the outside. However, the embodiment is not limited to what is illustrated, and the bezel region BZA may be disposed adjacent to only one side of the transmission region TA, or at least a portion of the bezel region may be omitted.

The display device DD may further include an optical layer OPL disposed between the display module DM and the window member CW. The optical layer OPL may be formed on the display module DM through a continuous process. The optical layer OPL may include a polarization plate or a color filter layer. For example, the optical layer OPL may include at least one of a retarder, a polarizer, a polarization film, or a polarization filter. For example, the optical layer OPL may include a plurality of color filters disposed in a regular arrangement. For example, the color filters may be arranged in consideration of the emission colors of the pixels. In addition, the optical layer OPL may further include a black matrix adjacent to the color filters.

FIG. 3 is a block diagram of the electronic apparatus EA according to an embodiment. Referring to FIG. 3, the electronic apparatus EA may include a first electronic module EM, a power module PSM, the display module DM, and the second electronic module ELM. The first electronic module EM, the power module PSM, the display module DM, and the second electronic module ELM may be accommodated in the accommodation space of the housing HAU illustrated in FIG. 2. The components of the first electronic module EM illustrated in FIG. 3 are illustrated as an example, and at least one component of the first electronic module EM may be omitted in consideration of an operation method, a use mode, or the like of the electronic apparatus EA, or additional components may be further included.

The display module DM may include a display panel DP and an input sensing part TP. The display panel DP may generate images, and the input sensing part TP may detect external inputs.

The first electronic module EM may include a control module E10, a wireless communication module E20, an image input module E30, a sound input module E40, a sound output module E50, a memory E60, an external interface module E70, and the like. The components of the first electronic module EM may be mounted on the display panel DP or electrically connected through a flexible circuit board. The first electronic module EM may be electrically connected to the power module PSM.

The control module E10 may control overall operations of the electronic apparatus EA. For example, the control module E10 activates or deactivates the display module DM in accordance with the user's input. The control module E10 may control the image input module E30, the sound input module E40, the sound output module E50, and the like in accordance with the user's input. The control module E10 may include at least one microprocessor.

The wireless communication module E20 may transmit/receive a wireless signal to/from another terminal using a wireless communication network such as a Bluetooth or a Wi-Fi. The wireless communication module E20 may transmit/receive a voice signal using a general communication line. The wireless communication module E20 may include a transmission circuit E22 which modulates a signal to be transmitted and transmits the modulated signal, and a reception circuit E24 which demodulates the received signal.

The image input module E30 may process image signals and convert the image signals into image data displayable on the display panel DP. The sound input module E40 may receive external sound signals from a microphone in a recording mode, a voice recognition mode, or the like, and convert the external sound signals into electrical voice data. The sound output module E50 may convert the sound data received from the wireless communication module E20 or the sound data stored in the memory E60, and output the sound data to the outside.

The external interface module E70 may serve as an interface which connects to an external charger, a wired/wireless data port, a card socket (for example, a memory card, a SIM/UIM card), and the like.

The power module PSM may provide power required for overall operations of the electronic apparatus EA. The power module PSM may include a typical battery. For example, a battery may include a primary cell which is not rechargeable, a secondary cell which is rechargeable, or a fuel cell. However, this is an example, and the embodiment is not limited thereto.

FIG. 4 is a cross-sectional view illustrating a portion taken along a line I-I′ in FIG. 2. FIG. 4 may be a cross-sectional view schematically illustrating a structure of the display module DM according to an embodiment.

Referring to FIG. 4, the display module DM may include the display panel DP and the input sensing part TP disposed on the display panel DP. The display panel DP may be a component which generates images. The display panel DP may be folded with respect to at least one folding axis FX1 (see FIG. 1B).

The display panel DP may include a base layer BS, a circuit layer DP-CL, a display element layer DP-EL, and an encapsulation layer TFE which are stacked sequentially. Unlike what is illustrated, an additional member may be further disposed between two adjacent layers among the base layer BS, the circuit layer DP-CL, the display element layer DP-EL, and the encapsulation layer TFE.

The base layer BS may provide a base surface on which the circuit layer DP-CL is disposed. The base layer BS may be a flexible substrate which is bendable, foldable, rollable, or the like. The base layer BS may be a glass substrate, a metal substrate, or a polymer substrate. However, the embodiment is not limited thereto, and the base layer BS may include an inorganic layer, an organic layer, or a composite material layer.

The circuit layer DP-CL may be disposed on the base layer BS. The circuit layer DP-CL may include an insulation layer, a semiconductor pattern, a conductive pattern, a signal line, and the like. The display element layer DP-EL may be disposed on the circuit layer DP-CL. The display element layer DP-EL may include a light-emitting element ED (see FIG. 6A) to be described later. For example, the light-emitting element ED (see FIG. 6A) may include an organic light-emitting material, an inorganic light-emitting material, an organic-inorganic light-emitting material, quantum dots, or quantum rods. For example, the light-emitting element ED (see FIG. 6A) may include a micro-LED or a nano-LED.

The encapsulation layer TFE may be disposed on the display element layer DP-EL. The encapsulation layer TFE may protect the display element layer DP-EL from moisture, oxygen, and/or foreign matter such as dust particles. The encapsulation layer TFE may include at least one inorganic layer. For example, the encapsulation layer TFE may include an inorganic layer, an organic layer, and an inorganic layer which are stacked sequentially.

The input sensing part TP may be disposed on the display panel DP. For example, the input sensing part TP may be disposed directly on the encapsulation layer TFE. For example, an adhesive member may be disposed between the input sensing part TP and the display panel DP.

In this specification, one component being directly disposed/provided/formed on another component indicates that no component is disposed/provided/formed between the one component and the other component. That is, when one component is ‘directly disposed/provided/formed’ on another component, the one component and the other component are in ‘contact’.

The input sensing part TP may detect an external input, change the external input into an input signal, and provide the input signal to the display panel DP. For example, the input sensing part TP may be a touch sensing part which detects a touch. The input sensing part TP may recognize a user's direct touch, a user's indirect touch, an object's direct touch, an object's indirect touch, or the like.

The input sensing part TP may detect at least one of a position of a touch or an intensity (pressure) of a touch applied from the outside. The input sensing part TP may have various structures or may be composed of various materials. For example, the input sensing part TP may detect an external input in a capacitive manner. The display panel DP may receive input signals from the input sensing part TP and generate images corresponding to the input signals.

FIG. 5 is an enlarged plan view illustrating a portion of the active region DM-DA according to an embodiment. Referring to FIG. 5, the active region DM-DA of the display module DM may include a light-emitting region PXA and a light-blocking region NPXA. The light-blocking region NPXA may surround the light-emitting region PXA.

The display module DM may include a plurality of light-emitting regions which emit light of different wavelength ranges. The light-emitting region PXA may include a first light-emitting region PXA-R, a second light-emitting region PXA-G, and a third light-emitting region PXA-B. For example, the first light-emitting region PXA-R may emit red light, the second light-emitting region PXA-G may emit green light, and the third light-emitting region PXA-B may emit blue light. However, the embodiment is not limited thereto and the first to third light-emitting regions PXA-R, PXA-G, and PXA-B may emit light of a different color other than red light, green light, and blue light.

Among the light-emitting regions PXA, an area of the third light-emitting region PXA-B which emits blue light may be the greatest, and an area of the second light-emitting region PXA-G which emits green light may be the smallest. Here, the term “area” refers to a planar area. However, this is an example, and areas of the first to third light-emitting regions PXA-R, PXA-G, and PXA-B are not limited thereto.

FIG. 5 illustrates that the first light-emitting region PXA-R and the third light-emitting region PXA-B are alternately arranged in a first row along the second direction DR2, and the second light-emitting region PXA-G is spaced apart from the first light-emitting region PXA-R and the third light-emitting region PXA-B and arranged in a second row. However, this is an example, and an arrangement of the first to third light-emitting regions PXA-R, PXA-G, and PXA-B is not limited thereto. In addition, the shapes of the first to third light-emitting regions PXA-R, PXA-G, and PXA-B when seen in a plan view are not limited to what is illustrated, and may be defined as shapes different from what is illustrated.

The light-blocking region NPXA may be a region between the neighboring light-emitting regions PXA-R, PXA-G, and PXA-B, and may be a region where a pixel-defining film PDL is disposed (see FIG. 6A). The light-emitting region PXA may be a region where a light-emitting element ED is disposed (see FIG. 6A).

FIG. 6A is a cross-sectional view illustrating the display panel DP according to an embodiment. FIG. 6A may be a cross-sectional view illustrating a portion corresponding to the first to third light-emitting regions PXA-R, PXA-G, and PXA-B and the light-blocking region NPXA adjacent to the first to third light-emitting regions PXA-R, PXA-G, and PXA-B illustrated in FIG. 5.

Referring to FIG. 6A, the base layer BS may include a single layer or a multi-layer. For example, the base layer BS may include a first synthetic resin layer, a single-layered or multi-layered inorganic layer, a second synthetic resin layer disposed on the single-layered or multi-layered inorganic layer. Each of the first synthetic resin layer and the second synthetic resin layer may include a polyimide-based resin. In addition, each of the first synthetic resin layer and the second synthetic resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, “˜˜” based resin indicates that it includes a functional group of “˜˜”.

The display panel DP may include a transistor (not illustrated) and a light-emitting element ED. The transistor (not illustrated) and the light-emitting element ED may be disposed on the base layer BS. The display panel DP may include a plurality of transistors and at least one capacitor for driving the light-emitting element ED. For example, the circuit layer DP-CL of the display panel DP may include a switching transistor and a driving transistor for driving the light-emitting element ED of the display element layer DP-EL.

The circuit layer DP-CL may include an insulation layer, a semiconductor pattern, a conductive pattern, a signal line, and the like. For example, the circuit layer DP-CL may include a plurality of connection electrodes CNE1, CNE2, and CNE3, a semiconductor pattern ST, a plurality of insulation layers BFL and INS1 to INS7, and a reflection layer RFL. The plurality of connection electrodes CNE1, CNE2, and CNE3, the semiconductor pattern ST, the plurality of insulation layers BFL and INS1 to INS7, and the reflection layer RFL may be disposed on the base layer BS.

The connection electrodes CNE1, CNE2, and CNE3 may include first to third connection electrodes CNE1, CNE2, and CNE3. The insulation layers BFL and INS1 to INS7 may include a buffer layer BFL and first to seventh insulation layers INS1 to INS7. However, this is an example, and at least one of insulation layers BFL and INS1 to INS7 may be omitted, or the circuit layer DP-CL may further include another insulation layer.

The buffer layer BFL may be disposed on the base layer BS. The buffer layer BFL may include an inorganic layer. The buffer layer BFL may enhance a bonding force between the base layer BS and the semiconductor pattern ST or the conductive pattern disposed on the buffer layer BFL.

The semiconductor pattern ST may be disposed on the buffer layer BFL. The semiconductor pattern ST may include amorphous silicon, low-temperature polysilicon, and/or polysilicon. However, the embodiment of the disclosure is not limited thereto. For example, the semiconductor pattern ST may include an oxide semiconductor pattern.

FIG. 6A only illustrates a portion of the semiconductor pattern ST, and the semiconductor pattern may be further disposed in other regions. The semiconductor pattern ST may be arranged in a selected pattern throughout the active region DM-DA (see FIG. 2). The semiconductor pattern ST may have different electrical properties depending on whether the semiconductor pattern is doped. The semiconductor pattern ST may include a first region having high conductivity, and a second region having low conductivity. The first region may be doped with an N-type dopant or a P-type dopant. A P-type transistor may include a doped region with the P-type dopant, and an N-type transistor may include a doped region with the N-type dopant. The second region may be an undoped region or a lightly doped region having a lower doping concentration than the first region.

The first region may have a higher conductivity than the second region, and serve as an electrode or a signal line. The second region may be a channel (or an active) of a transistor. That is, the second region of the semiconductor pattern ST may be a channel of a transistor, and the first region may be a source or a drain of a transistor, or may be a connection electrode or a connection signal line. FIG. 6A illustrates an example in which the semiconductor pattern ST is a portion of a drain of a transistor or a portion a connection signal line.

The first insulation layer INS1 may cover the semiconductor pattern ST and be disposed on the buffer layer BFL. The second insulation layer INS2 may be disposed on the first insulation layer INS1. The third insulation layer INS3 may be disposed on the second insulation layer INS2.

The semiconductor pattern ST and the light-emitting element ED may be electrically connected through the first to third connection electrodes CNE1, CNE2, and CNE3. The connection electrodes for electrically connecting the semiconductor pattern ST to the light-emitting element ED are not limited thereto, and one or two among the first to third connection electrodes CNE1, CNE2, and CNE3 may be omitted, or an additional connection electrode may be further included.

The first connection electrode CNE1 may be disposed on the third insulation layer INS3. The first connection electrode CNE1 may be connected to the semiconductor pattern ST through a first contact hole CTH1 which extends through the first to third insulation layers INS1 to INS3. The fourth insulation layer INS4 may cover the first connection electrode CNE1 and be disposed on the third insulation layer INS3. The fifth insulation layer INS5 may be disposed on the fourth insulation layer INS4. For example, the fifth insulation layer INS5 may be a planarization layer.

The second connection electrode CNE2 may be disposed on the fifth insulation layer INS5. The second connection electrode CNE2 may be connected to the first connection electrode CNE1 through a second contact hole CTH2 which extends through the fourth and fifth insulation layers INS4 and INS5. The sixth insulation layer INS6 may cover the second connection electrode CNE2 and be disposed on the fifth insulation layer INS5.

The third connection electrode CNE3 may be disposed on the sixth insulation layer INS6. The third connection electrode CNE3 may be connected to the second connection electrode CNE2 through a third contact hole CTH3 which extends through the sixth insulation layer INS6. The seventh insulation layer INS7 may cover the third connection electrode CNE3 and be disposed on the sixth insulation layer INS6. The seventh insulation layer INS7 may be disposed on the reflection layer RFL. During the manufacturing process of the display panel DP, the third connection electrode CNE3 and the reflection layer RFL may be formed through the same process. The third connection electrode CNE3 and at least a portion of the reflection layer RFL may be disposed on a same layer and may include the same material.

The sixth insulation layer INS6 may have a first opening S6_OP. The first opening S6_OP may penetrate the sixth insulation layer INS6 in the thickness direction DR3. An upper surface of the fifth insulation layer INS5 may be exposed through the first opening S6_OP of the sixth insulation layer INS6. The reflection layer RFL may be disposed on the fifth insulation layer INS5. The reflection layer RFL may be disposed on the upper surface of the fifth insulation layer INS5 exposed through the first opening S6_OP of the sixth insulation layer INS6. That is to say, the reflection layer RFL includes a first portion disposed on an upper surface of the fifth insulation layer INS5, a second portion disposed on a side surface of the sixth insulation layer INS6, and a third portion disposed on an upper surface of the sixth insulation layer INS6. The first opening S6_OP of the sixth insulation layer INS6 may be provided in plurality. The plurality of the first openings S6_OP may be spaced apart from each other in one direction perpendicular to the thickness direction DR3.

The reflection layer RFL may include a plurality of reflection layers. The reflection layer RFL may include first to third reflection layers RF-1, RF-2, and RF-3. The first to third reflection layers RF-1, RF-2, and RF-3 may be spaced apart from each other in one direction perpendicular to the thickness direction DR3. The first to third reflection layers RF-1, RF-2, and RF-3 may respectively include portions disposed in the first openings S6_OP. The first to third reflection layers RF-1, RF-2, and RF-3 may be spaced apart from each other in the light-blocking region NPXA. The first to third reflection layers RF-1, RF-2, and RF-3 may be spaced apart from each other in the light-blocking region NPXA, and the third connection electrode CNE3 may be disposed between first to third reflection layers RF-1, RF-2, and RF-3.

Unlike what is illustrated in FIG. 6A, the first to third reflection layers RF-1, RF-2, and RF-3 may have an integral shape. When the first to third reflection layers RF-1, RF-2, and RF-3 have an integral shape, an opening which separates the third connection electrode CNE3 from the integrally formed reflection layer RFL may be defined in the reflection layer RFL. The opening which separates the third connection electrode CNE3 may be disposed in an area corresponding to the light-blocking region NPXA.

In an embodiment, the reflection layer RFL may include metal. The reflection layer RFL may include metal which has approximately zero light transmittance. The reflection layer RFL may have approximately zero light transmittance for light of a visible light wavelength range, and may reflect the light. For example, the reflection layer RFL may include at least one of Ag, Mg, Cu, Al, Pt, Pd, Au, Ni, Nd, Ir, Cr, Li, Ca, Mo, Ti, and W. However, this is an example, and the reflection layer RFL may include, without limitation, metal that easily reflects light.

The reflection layer RFL may be disposed under the light-emitting element ED. Specifically, the reflection layer RFL may be disposed under first electrodes EL1-1, EL1-2, and EL1-3 of the light-emitting element ED. The reflection layer RFL may change a path of light propagating downward from the light-emitting element ED to an upward direction. The light-emitting element ED according to an embodiment may emit light from both sides. That is to say, the light emitted from the light-emitting element ED would travel both downward and upward. When light emitted from the light-emitting element ED propagates downward, the reflection layer RFL may reflect the light traveling downward to make the light proceed upward. As the amount of the light traveling downward increases, the light emitted from the display surface FS (see FIG. 1A) would decrease, thereby resulting in the increase of loss of light and degradation of the display quality. The reflection layer RFL may minimize the loss of light by reflecting the light propagating downward to make the light emit through the display surface FS. Thus, according to an embodiment, the display panel DP and the electronic apparatus EA (see FIG. 1A) which include the reflection layer RFL may exhibit excellent display quality. The reflection layer RFL will be described in further detail later.

Each of the first to seventh insulation layers INS1 to INS7 may include an inorganic layer or an organic layer. For example, the first to the fourth insulation layers INS1 to INS4 may be an inorganic layers which include inorganic materials. For example, the fifth to seventh insulation layers INS5 to INS7 may be organic layers which include organic materials.

For example, the inorganic layer may include at least one of aluminum oxide, titanium oxide, silicon oxide, silicon oxynitride, zirconium oxide, or hafnium oxide. The organic layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin.

The display element layer DP-EL may include a pixel-defining film PDL and the light-emitting element ED. The light-emitting element ED may emit light. For example, the light-emitting element ED may include an organic light-emitting material, an inorganic light-emitting material, an organic-inorganic light-emitting material, quantum dots, or quantum rods. For example, the light-emitting element ED may include a micro-LED or a nano-LED.

The light-emitting element ED may include first to third light-emitting elements ED-1, ED-2, and ED-3. The first to third light-emitting elements ED-1, ED-2, and ED-3 may respectively include the first electrodes EL1-1, EL1-2, and EL1-3, at least one of functional layers FL-R, FL-G, and FL-B respectively disposed on the first electrodes EL1-1, EL1-2, and EL1-3, and a second electrode EL2 disposed on the at least one of the functional layers FL-R, FL-G, and FL-B. Although not illustrated, the first to third light-emitting elements ED-1, ED-2, and ED-3 may further include an element-capping layer disposed on the second electrode EL2.

The first electrodes EL1-1, EL1-2, and EL1-3 may be disposed on the seventh insulation layer INS7. The first electrodes EL1-1, EL1-2, and EL1-3 may be connected to the third connection electrode CNE3 through a fourth contact hole CTH4 which extends through the seventh insulation layer INS7. The first electrodes EL1-1, EL1-2, and EL1-3 may be electrically connected to the semiconductor pattern ST through the first to third connection electrodes CNE1, CNE2, and CNE3.

The first electrodes EL1-1, EL1-2, and EL1-3 may include a metal material, a metal alloy, or a conductive compound. The first electrodes EL1-1, EL1-2, and EL1-3 may be anodes or cathodes. However, the embodiment is not limited thereto. The first electrodes EL1-1, EL1-2, and EL1-3 may be referred to as pixel electrodes.

In an embodiment, the first electrodes EL1-1, EL1-2, and EL1-3 may include transmissive electrodes or transflective electrodes (in other words, semi-transmissive electrodes). The first electrodes EL1-1, EL1-2, and EL1-3 are not reflective electrodes. Reflective electrodes are used for light-emitting elements which perform top emission.

The first electrodes EL1-1, EL1-2, and EL1-3 may include at least one selected from among Ag, Mg, Cu, Al, Pt, Pd, Au, Ni, Nd, Ir, Cr, Li, Ca, LiF, Mo, Ti, W, In, Sn, and Zn, a compound including at least two selected therefrom, a mixture including at least two selected therefrom, or an oxide thereof.

When the first electrodes EL1-1, EL1-2, and EL1-3 are transmissive electrodes, the first electrodes EL1-1, EL1-2, and EL1-3 may include a transparent metal oxide such as indium tin oxide (ITO), indium zinc oxide (IZO), zinc oxide (ZnO), indium tin zinc oxide (ITZO). When the first electrodes EL1-1, EL1-2, and EL1-3 are transflective electrodes, the first electrodes EL1-1, EL1-2, and EL1-3 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or a mixture thereof (for example, a mixture of Ag and Mg). For example, the first electrodes EL1-1, EL1-2, and EL1-3 may include ITO. However, the embodiment of the disclosure is not limited thereto. For example, the first electrodes EL1-1, EL1-2, and EL1-3 may have a multi-layered structure which includes a transflective film including the aforementioned materials, and a transparent conductive film including indium tin oxide (ITO), indium zinc oxide (IZO), zinc oxide (ZnO), indium tin zinc oxide (ITZO), or the like.

The first to third light-emitting elements ED-1, ED-2, and ED-3 including the first electrodes EL1-1, EL1-2, and EL1-3, which are transmissive electrodes or transflective electrodes, may perform double-sided emission. The double-sided emission may indicate light emission which includes top emission and bottom emission. The double-sided emission may be emission of light in both the upper direction and the lower direction. In contrast, the top emission may be emission of light only in the upper direction.

Compared to the light-emitting element which only performs top emission, the light-emitting element ED which performs double-sided emission may improve the display quality by reducing color differences according to viewing angles. The light-emitting element ED which performs double-sided emission may be non-resonant. In the light-emitting element which only performs top emission, the first electrode (for example, an anode) includes a reflective electrode which has a large amount of light emitted from the front surface and a relatively small amount of light emitted from the side surfaces, thereby resulting in degraded display quality in the side surfaces. Thus, the light-emitting elements which only perform top emission show great color differences according to viewing angles.

The color differences according to viewing angles indicate that the color is viewed differently depending on a position from which the light emitting surface is seen. That is, the color differences may indicate a phenomenon where the color appears differently when viewed from the front compared to when viewed from the side. For example, the color differences may indicate a phenomenon where white light is perceived when the display surface of the display device emitting white light is seen from the front, but blue or yellow component is partially perceived due to the variation of the light wavelength variation when seen from the side. Such a phenomenon may be defined as white angle dependency (WAD).

In an embodiment, the light-emitting element ED including the first electrode EL1-1, EL1-2, or EL1-3, which is a transmissive electrode or transflective electrode, may perform double-sided emission. The light-emitting element ED which performs double-sided emission may emit a relatively large amount of light through the sides compared to the light-emitting element which performs top emission. Thus, the display panel DP including the light-emitting element ED which performs double-sided emission may reduce the color differences according to viewing angles and thus exhibit excellent display quality.

The pixel-defining film PDL may be disposed on the seventh insulation layer INS7. Second openings PX_OP which extends to portions of the first electrodes EL1-1, EL1-2, and EL1-3 may be defined in the pixel-defining film PDL. The second openings PX_OP may penetrate the pixel-defining film PDL in the thickness direction DR3. The portions of the first electrodes EL1-1, EL1-2, and EL1-3 exposed by the second openings PX_OP may define light-emitting regions PXA-R, PXA-G, and PXA-B. The second openings PX_OP may be referred to as light-emitting openings or pixel openings.

The pixel-defining film PDL may include a polymer resin. For example, the pixel-defining film PDL may include a polyacrylate-based resin or a polyimide-based resin. The pixel-defining film PDL may include a black pigment and/or black dye. However, this is an example, and a material included in the pixel-defining film PDL is not limited thereto.

At least one of the functional layers FL-R, FL-G, and FL-B may be disposed in a region corresponding to the second opening PX_OP. However, the embodiment is not limited thereto. For example, at least one of the functional layers FL-R, FL-G, and FL-B may be disposed as a common layer and overlap the light-emitting regions PXA-R, PXA-G, and PXA-B and the light-blocking region NPXA. At least one of the functional layers FL-R, FL-G, and FL-B may include an organic light-emitting material and/or an inorganic light-emitting material. At least one of the functional layers FL-R, FL-G, and FL-B may emit any one of light among red light, green light, and blue light.

The first light-emitting element ED-1 may include a first functional layer FL-R. The first functional layer FL-R may be disposed in an area corresponding to the first light-emitting region PXA-R and emit red light. The second light-emitting element ED-2 may include a second functional layer FL-G. The second functional layer FL-G may be disposed in an area corresponding to the second light-emitting region PXA-G and emit green light. The third light-emitting element ED-3 may include a third functional layer FL-B. The third functional layer FL-B may be disposed in an area corresponding to the third light-emitting region PXA-B and emit blue light. However, the embodiment is not limited thereto. For example, the first to third functional layers FL-R, FL-G, and FL-B may emit light of the same color.

The second electrode EL2 may be provided as a common layer overlapping the first to third light-emitting regions PXA-R, PXA-G, and PXA-B and the light-blocking region NPXA. The second electrode EL2 may be a common electrode. The second electrode EL2 may be a cathode or an anode, but the embodiment is not limited thereto. For example, when the first electrodes EL1-1, EL1-2, and EL1-3 are anodes, the second electrode EL2 may be a cathode, and when the first electrodes EL1-1, EL1-2, and EL1-3 are cathodes, the second electrode EL2 may be an anode.

In the light-emitting element ED according to an embodiment, the second electrode EL2 may be a transmissive electrode or a transreflective electrode. When the second electrode EL2 is a transmissive electrode, the second electrode may include transparent metal oxide such as indium tin oxide (ITO), indium zinc oxide (IZO), zinc oxide (ZnO), indium tin zinc oxide (ITZO).

When the second electrode EL2 is a transreflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or a mixture (for example, AgMg, AgYb, or MgYb) including the same. In another example, the second electrode EL2 may have a multi-layered structure which includes a transflective film including the aforementioned materials and a transparent conductive film including indium tin oxide (ITO), indium zinc oxide (IZO), zinc oxide (ZnO), indium tin zinc oxide (ITZO), or the like. For example, the second electrode EL2 may include the aforementioned metal materials, a combination of the metal materials including at least two selected from among the aforementioned metal materials, or oxides of the aforementioned metal materials.

The encapsulation layer TFE may be disposed on the display element layer DP-EL. The encapsulation layer TFE may be disposed on the second electrode EL2 and cover the light-emitting element ED. The encapsulation layer TFE may include a plurality of thin films.

The encapsulation layer TFE may include at least one inorganic film. For example, the encapsulation layer TFE may include inorganic films disposed on the second electrode EL2 and an organic film disposed between the inorganic films. The inorganic film may protect the light-emitting element ED from moisture/oxygen, and the organic film may protect the light-emitting element ED from foreign matter such as dust particles.

FIG. 6B is an enlarged cross-sectional view illustrating a region XX′ in FIG. 6A. Referring to FIG. 6B, the first functional layer FL-R may include a hole control layer HCL, a light-emitting layer EML-R disposed on the hole control layer HCL, and an electron control layer TCL disposed on the light-emitting layer EML-R. Hereinafter, the description of the first functional layer FL-R may be similarly applied to the second and the third functional layers FL-G and FL-B illustrated in FIG. 6A. Hereinafter, the description of the first electrode EL1-1 may be similarly applied to the first electrodes EL1-2 and EL1-3 of the second and the third light-emitting elements ED-2 and ED-3 illustrated in FIG. 6A. Hereinafter, the description of the first reflection layer RF-1 may be similarly applied to the second and the third reflection layers RF-2 and RF-3 illustrated in FIG. 6A.

The light-emitting layer EML-R may be disposed between the first electrode EL1-1 and the second electrode EL2. The light-emitting layer EML-R may include an organic light-emitting material and/or an inorganic light-emitting material. For example, the light-emitting layer EML-R may include a fluorescent light-emitting material or a phosphorescent light-emitting material. However, this is an example, and the material included in the light-emitting layer EML-R is not limited thereto.

The hole control layer HCL may be disposed between the first electrode EL1-1 and the light-emitting layer EML-R. The hole control layer HCL may include at least one of a hole injection layer, a hole transport layer, or an electron blocking layer. The hole control layer HCL may include a hole injection material and/or a hole transport material, which are widely known to the ordinary skilled in the art.

The electron control layer TCL may be disposed between the light-emitting layer EML-R and the second electrode EL2. The electron control layer TCL may include at least one of an electron injection layer, an electron transport layer, or a hole blocking layer. The electron control layer TCL may include an electron injection material and/or an electron transport material, which are widely known to the ordinary skilled in the art.

The first electrode EL1-1 may include a first part E-P1 arranged perpendicular to the thickness direction DR3 and a second part E-P2 which extends from the first part E-P1 and is inclined with respect to the thickness direction DR3. The first part E-P1 of the first electrode EL1-1 may be disposed in the first opening S6_OP of the sixth insulation layer INS6. The second part E-P2 of the first electrode EL1-1 may be disposed on an inner surface S6_F (or a side surface) of the sixth insulation layer INS6 which defines the first opening S6_OP.

In addition, the first electrode EL1-1 may further include a third part E-P3 which extends from the second part E-P2 and is arranged perpendicular to the thickness direction DR3. The third part E-P3 may be disposed on the seventh insulation layer INS7. The third part E-P3 and the first part E-P1 may not overlap. In the thickness direction DR3, the shortest length from the fifth insulation layer INS5 to the third part E-P3 may be greater than the shortest length from the fifth insulation layer INS5 to the first part E-P1.

In a cross sectional view, the first part E-P1 and the second part E-P2 may form a portion of an inverted trapezoid shape. The first part E-P1 may correspond to a lower surface of the inverted trapezoid, and the second part E-P2 may correspond to a side surface of the inverted trapezoid. The second part E-P2 may extend in a direction not overlapping the first part E-P1, excluding the boundary in contact with the first part E-P1.

The second part E-P2 may be inclined at a first acute angle θ_{E} with respect to an imaginary plane VP extending from the first part E-P1 and perpendicular to the thickness direction DR3. The first acute angle θ_{E} may be less than about 50°. The first acute angle θ_{E} may be equal to or greater than about 1°. The imaginary plane VP illustrated in FIG. 6B is a virtual plane illustrated for explanation, and is perpendicular to the thickness direction DR3. The first acute angle θ_{E} may be an angle between the lower surface and the side surface of the inverted trapezoid.

The first acute angle θ_{E} may be adjusted by the seventh insulation layer INS7 disposed adjacent to the first electrode EL1-1. The first electrode EL1-1 may be disposed directly on the seventh insulation layer INS7. For example, one region and another region in the seventh insulation layer INS7 may be formed to have different thicknesses, and thus the first electrode EL1-1 including the second part E-P2 inclined at the first acute angle θ_{E} may be formed on the seventh insulation layer INS7.

Referring to FIG. 6C, inside the light-emitting element, when light at an angle of less than about 40° with respect to a plane VP-1 perpendicular to the thickness direction DR3 is directed upward, total reflection occurs. FIG. 6C is a cross-sectional view illustrating only a portion of the display panel DP (see FIG. 6A) for the convenience of explanation, and components are schematically illustrated.

In FIG. 6C, two planes VP and VP-1 are perpendicular to the thickness direction DR3 and parallel to each other. In FIG. 6C, OA indicates an angle formed by the plane VP-1 and light LT emitted from the light-emitting layer EML-R (see FIG. 6B). OA is an angle of incidence of the light LT and is less than about 40°. Hereinafter, OA will be referred to as a propagation angle.

In FIG. 6C, E_F indicates a boundary surface between the display element layer DP-EL (see FIG. 6A), and the encapsulation layer TFE (see FIG. 6A). Since the propagation angle θ_{A} is equal to or less than about 40°, the light LT is totally reflected at the boundary surface E_F. An angle of about 40° is a calculated value representing an angle, at which total reflection occurs, from refractive indices of the components (for example, the functional layer, the second electrode, and the encapsulation layer) disposed on the first electrode EL1-1.

The sum of the propagation angle θ_{A} and the first acute angle θ_{E} is about 90°. To prevent total reflection, the propagation angle θ_{A} should be equal to or greater than about 40°, and when the propagation angle θ_{A} is equal to or greater than about 40°, the first acute angle θ_{E} is less than about 50°. Accordingly, the display panel DP (see FIG. 6A) including the second part E-P2 inclined at the first acute angle θ_{E}, which is less than about 50°, with respect to the plane VP perpendicular to the thickness direction DR3 may have minimal loss of light caused by the total reflection, and thus exhibit excellent display quality.

Referring back to FIG. 6B, the second opening PX_OP may overlap the first opening S6_OP. For example, in one direction perpendicular to the thickness direction DR3, a first width WT1 of the first opening S6_OP may be smaller than a second width WT2 of the second opening PX_OP. The first width WT1 of the first opening S6_OP may be the maximum width of the first opening S6_OP in one direction perpendicular to the thickness direction DR3. The second width WT2 of the second opening PX_OP may be the minimum width of the second opening PX_OP in one direction perpendicular to the thickness direction DR3.

The first reflection layer RF-1 may include a first part R-P1 disposed in the first opening S6_OP of the sixth insulation layer INS6, and a second part R-P2 extending from the first part R-P1 and disposed on the inner surface S6_F of the sixth insulation layer INS6. The first part R-P1 of the first reflection layer RF-1 may extend in one direction perpendicular to the thickness direction DR3. The first part R-P1 of the first reflection layer RF-1 may be disposed on an upper surface of the fifth insulation layer INS5 exposed through the first opening S6_OP.

The first part R-P1 of the first reflection layer RF-1 may overlap the first part E-P1 of the first electrode EL1-1. In one direction perpendicular to the thickness direction DR3, a length of the first part R-P1 of the first reflection layer RF-1 may be greater than a length of the first part E-P1 of the first electrode EL1-1. In the thickness direction DR3, the first part R-P1 of the first reflection layer RF-1 and the first part E-P1 of the first electrode EL1-1 may be spaced apart. In the thickness direction DR3, a portion of the seventh insulation layer INS7 may be disposed between the first part R-P1 of the first reflection layer RF-1 and the first part E-P1 of the first electrode EL1-1. In one direction perpendicular to the thickness direction DR3, the second part R-P2 of the first reflection layer RF-1 and the second part E-P2 of the first electrode EL1-1 may be spaced apart. In one direction perpendicular to the thickness direction DR3, a portion of the seventh insulation layer INS7 may be disposed between the second part R-P2 of the first reflection layer RF-1 and the second part E-P2 of the first electrode EL1-1. The second part R-P2 of the first reflection layer RF-1 and the first part E-P1 of the first electrode EL1-1 may not overlap.

In addition, the first reflection layer RF-1 may further include a third part R-P3 extending from the second part R-P2 and arranged perpendicular to the thickness direction DR3. The third part R-P3 of the first reflection layer RF-1 may be disposed on the sixth insulation layer INS6. The third part R-P3 of the first reflection layer RF-1 may not overlap the first part R-P1 of the first reflection layer RF-1. The third part R-P3 and the first part R-P1 of the first reflection layer RF-1 may be disposed on different layers.

In a cross sectional view, the first part R-P1 and the second part R-P2 may form a portion of an inverted trapezoid shape. The first part R-P1 may correspond to a lower surface of the inverted trapezoid, and the second part R-P2 may correspond to a side surface of the inverted trapezoid. The second part R-P2 may extend in a direction not overlapping the first part R-P1, excluding the boundary in contact with the first part R-P1.

The second part R-P2 may be inclined at a second acute angle θR with respect to a plane S5_F which is a lower surface of the sixth insulation layer INS6 and perpendicular to the thickness direction DR3. In FIG. 6B, the plane S5_F adjacent to the second part R-P2 may be an upper surface of the fifth insulation layer INS5. The second acute angle θR may be less than about 50°. The second acute angle θR may be greater than 0°. The second acute angle θR may be an angle between the lower surface and the side surface of the inverted trapezoid.

The second acute angle θR may be adjusted by the sixth insulation layer INS6 disposed adjacent to the reflection layer RFL. The second part R-P2 of the reflection layer RFL may be disposed directly on the inner surface S6_F of the sixth insulation layer INS6. For example, one region and another region in the sixth insulation layer INS6 may be formed to have different thicknesses, and thus the reflection layer RFL including the fourth part R-P2 inclined at the second acute angle θ_{R} may be formed on the sixth insulation layer INS6.

If the second acute angle is equal to or greater than 50°, light reflected from the second part R-P2 of the first reflection layer RF-1 is totally reflected at the boundary surface E_F (see FIG. 6C). On the contrary, the second part R-P2 inclined at the second acute angle θ_{R}, which is less than 50°, minimizes loss of light by preventing the total reflection.

FIG. 6D is a cross-sectional view illustrating a region XX′ according to an embodiment of the inventive concept. FIG. 6D differs in the first acute angle θ_{E1} from FIG. 6B. FIG. 6D may be a drawing illustrating the case where the first acute angle θ_{E1} is relatively very small, while the first acute angle θ_{E1} is within a range less than about 50°.

The second acute angle θR may satisfy the following Expression 1. The second acute angle θR which satisfies the Expression 1 may prevent total reflection.

$${A}_{2} \leq ( 50 + {A}_{1} ) / 2 \qquad [ Expression 1 ]$$

In the Expression 1, A₁ is the first acute angle θ_{E} and A₂ is the second acute angle θR. According to the Expression 1, the second acute angle θR may be less than or equal to a value obtained by dividing the sum of 50 and the first acute angle θ_{E} by 2. Light reflected from the second part R-P2 of the reflection layer RFL inclined at the second acute angle θR greater than the value obtained by dividing the sum of 50 and the first acute angle θ_{E} by 2 cannot be emitted and is totally reflected. In contrast, light reflected from the second part R-P2 inclined at the second acute angle θR less than or equal to a value obtained by dividing the sum of 50 and the first acute angle θ_{E} by 2 can be emitted upward, and the second part R-P2 may minimize the loss of light.

FIG. 7A is a cross-sectional view illustrating a display panel DP-1 according to an embodiment of the inventive concept. FIG. 7B is an enlarged cross-sectional view illustrating a region YY′ in FIG. 7A. Hereinafter, with regard to the descriptions of FIGS. 7A and 7B, the contents duplicated with those described with reference to FIGS. 1 to 6D will not be described again, and differences will be mainly described.

The display panel DP-1 of FIG. 7A differs in a reflection layer RFL-1 from the display panel DP of FIG. 6A. The reflection layer RFL-1 may include first to third reflection layers RF-11, RF-12, and RF-13. Each of the first to third reflection layers RF-11, RF-12, and RF-13 may include a portion which overlaps the first part E-P1 of the first electrodes EL1-1, EL1-2, and EL1-3 may not be parallel to one direction perpendicular to the thickness direction DR3.

Referring to FIG. 7B, a first part R-PIS of the first reflection layer RF-11 may be inclined at a third acute angle θ_{RS} with respect to a plane VP-S perpendicular to the thickness direction DR3. The plane VP-S in FIG. 7B is a virtual plane illustrated for explanation, and the plane is perpendicular to the thickness direction DR3. The third acute angle θ_{RS} may be less than 25°. If the third acute angle is equal to or greater than 25°, light reflected from the first part R-PIS of the first reflection layer RF-11 is totally reflected at the boundary surface E_F (see FIG. 6C). On the contrary, the first reflection layer RF-11 according to an embodiment includes the first part R-PIS inclined at the third acute angle θRS of less than 25°, thereby preventing the occurrent of the total reflection.

An upper surface S5_F1 of a fifth insulation layer INS5 adjacent to the first part R-PIS may not be flat. The upper surface S5_F1 of the fifth insulation layer INS5 may be adjacent to a sixth insulation layer INS6 and spaced apart from the fourth insulation layer INS4 (see FIG. 7A). A lower surface of the fifth insulation layer INS5 may be disposed between the upper surface S5_F1 of the fifth insulation layer INS5 and the fourth insulation layer INS4. The fifth insulation layer INS5 is disposed under the first part R-PIS which has an inclined shape, and the upper surface S5_F1 of the fifth insulation layer INS5 may not be flat. In the fifth insulation layer INS5, a thickness of one region overlapping the first part R-PIS may be smaller than a thickness of another region not overlapping the first part R-PIS.

FIG. 8 is a graph showing brightness versus angle in a display panel according to Comparative Example and Examples and showing simulation results. The angle 0° may indicate that the display panel is viewed from the front, and the brightness in FIG. 8 may represent a relative brightness while the brightness as seen from the front is set to 1. The angle about 45° may indicate that the display panel is viewed from a position at an angle of about 45° from the front. Comparative Example is a display panel including a light-emitting element which only performs top emission, and Examples 1 and 2 are display panels including a light-emitting element which performs double-sided emission. Example 1 and Example 2 show results from the same display panel, and Example 1 shows a brightness as seen from a front surface and Example 2 shows a brightness as seen from a rear surface.

The following Table 1 shows brightnesses of display panels as seen from a position at an angle of about 45° in the same display panel as the Comparative Example and the Examples in FIG. 8. In Table 1, ‘LvA’ shows a relative brightness value as seen from a position at an angle of about 45°, when the brightness as seen from the front is set to 100%. ‘dLvA’ in Table 1 shows a degree of change in brightness for each change in the angle by 1°, when the brightness as seen from the front is set to 100%. Greater ‘dLvA’ indicates greater color differences according to viewing angles.

TABLE 1

| | LvA | dLvA |
|---|---|---|
| Comparative Example | 39% | 2.11% |
| Example 1 | 106% | 1.10% |
| Example 2 | 105% | 0.01% |

Referring to Table 1 and FIG. 8, compared to the display panel according to Comparative Example, it may be seen that the display panel according to Examples 1 and 2 shows excellent brightness as seen from a position at an angle of about 45°. In addition, compared to the display panel according to Comparative Example, it may be seen that the display panel according to Examples 1 and 2 maintains excellent brightness even when the angle becomes greater. The expression, an ‘angle becomes greater,’ above may indicate that the display panel is viewed at a lateral position farther away from the front. It may be seen that the display panel according to Comparative Example including a light-emitting element which only performs top emission has great color differences according to viewing angles. It may be seen that the display panel according to Examples 1 and 2 including a light-emitting element which performs double-sided emission has small color differences according to viewing angles. Thus, in an embodiment, it may be seen that a display panel including a light-emitting element which performs double-sided emission will show excellent display quality.

FIG. 9 is a cross-sectional view illustrating an input sensing part TP according to an embodiment. FIG. 9 may be a cross-sectional view schematically illustrating a structure of the input sensing part TP illustrated in FIG. 4.

Referring to FIG. 9, the input sensing part TP may include a first sensing insulation layer IS-IL1, a second sensing insulation layer IS-IL2, and a third sensing insulation layer IS-IL3. The input sensing part TP may include at least one conductive layer disposed on the sensing insulation layers. The input sensing part TP may include a first conductive layer IS-CL1 and a second conductive layer IS-CL2.

The first sensing insulation layer IS-IL1 may be disposed on the encapsulation layer TFE (see FIG. 4). The first sensing insulation layer IS-IL1 may include at least one inorganic insulation layer. The first sensing insulation layer IS-IL1 may be in contact with the encapsulation layer TFE (see FIG. 4). However, the embodiment of the disclosure is not limited thereto. For example, the first sensing insulation layer IS-IL1 may be omitted, and in this case, the first conductive layer IS-CL1 may be in contact with the encapsulation layer TFE (see FIG. 4).

The first conductive layer IS-CL1 may be disposed on the first sensing insulation layer IS-IL1. The first conductive layer IS-CL1 may include a plurality of first conductive patterns. The plurality of the first conductive patterns may be disposed on the first sensing insulation layer IS-IL1. The second sensing insulation layer IS-IL2 may be disposed on the first sensing insulation layer IS-IL1.

The second conductive layer IS-CL2 may be disposed on the second sensing insulation layer IS-IL2. The second conductive layer IS-CL2 may include a plurality of second conductive patterns. The plurality of the second conductive patterns may be disposed on the second sensing insulation layer IS-IL2. Each of the plurality of the first conductive patterns of the first conductive layer IS-CL1 and the plurality of the second conductive patterns of the second conductive layer IS-CL2 may include a mesh pattern.

The third sensing insulation layer IS-IL3 may cover the second conductive layer IS-CL2 and may be disposed on the second sensing insulation layer IS-IL2. Each of the second sensing insulation layer IS-IL2 and the third sensing insulation layer IS-IL3 may include an inorganic insulation layer or an organic insulation layer.

Each of the first conductive layer IS-CL1 and the second conductive layer IS-CL2 may have a single layered structure, or a multi-layered structure in which layers are stacked along the thickness direction DR3. The conductive layers IS-CL1 and IS-CL2 having a single layered structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), and indium zinc tin oxide (IZTO). In addition, the transparent conductive layer may include a conductive polymer such as PEDOT, a metal nanowire, graphene, or the like.

The conductive layers IS-CL1 and IS-CL2 having a multi-layered structure may include metal layers. The metal layers may have, for example, a three-layered structure of titanium (Ti)/aluminum (Al)/titanium (Ti). The conductive layers IS-CL1 and IS-CL2 having a multi-layered structure may include at least one metal layer and at least one transparent conductive layer.

FIG. 10 is a perspective view illustrating an electronic apparatus EA-a according to an embodiment of the inventive concept. Hereinafter, with regard to the descriptions of FIG. 10, the contents duplicated with those described with reference to FIGS. 1 to 9 will not be described again, and differences will be mainly described.

FIG. 10 illustrates an example in which the electronic apparatus EA-a is implemented as a monitor. The electronic apparatus EA-a may include a display panel DP. The electronic apparatus EA-a may further include a first support part SP-1 and a second support part SP-2 disposed on the first support part SP-1. The first support part SP-1 may be a support part disposed on the lowest portion of the monitor, and the first support part SP-1 may have a greater area than the second support part SP-2. Unlike what is illustrated, any one of the first and the second support parts SP-1 and SP-2 may be omitted.

The electronic apparatus EA-a may include a display region F-A, a non-display region F-NA, and a sub region MH-a. The display region F-A may be a region activated in response to an electrical signal. The display region F-A may be a region on which an image is displayed. The electronic apparatus EA-a may display an image toward the third direction DR3.

The non-display region F-NA may be adjacent to the display region F-A. A light transmittance of the non-display region F-NA may be lower than a light transmittance of the display region F-A. The non-display region F-NA may not be optically transparent and have a color. The non-display region F-NA may surround the display region F-A. The second electronic module ELM (see FIGS. 3 and 4) may be disposed in a region corresponding to the sub region MH-a.

FIG. 11A is a perspective view illustrating an electronic apparatus EA-b according to an embodiment of the inventive concept. FIG. 11B is an exploded perspective view of the electronic apparatus EA-b illustrated in FIG. 11A. Hereinafter, with regard to the descriptions of FIGS. 11A and 11B, the contents duplicated with those described with reference to FIGS. 1 to 10 will not be described again, and differences will be mainly described.

FIG. 11A illustrates an example in which the electronic apparatus EA-b is implemented as a smartphone. Referring to FIG. 11A, the electronic apparatus EA-b may include a display surface FS-b. The electronic apparatus EA-b may provide an image IM to a user through the display surface FS-b. The electronic apparatus EA may display the image IM toward the third direction DR3 through the display surface FS-b that is parallel to each of the first direction axis DR1 and the second direction axis DR2.

The electronic apparatus EA-b may detect an external input applied from the outside. An external input may include various types of inputs provided from the outside of the electronic apparatus EA-b.

The display surface FS-b may include a display region F-Ab, a non-display region F-NAb, and a sub region MH-b. The display region F-Ab may be a region activated in response to an electrical signal. The display region F-Ab may be a region in which the image IM is displayed and which is capable of detecting various types of external inputs.

The display region F-Ab may include a flat surface defined by the first direction axis DR1 and the second direction axis DR2. The display region F-Ab may include a curved surface bent from at least one side of the flat surface defined by the first direction axis DR1 and the second direction axis DR2. The electronic apparatus EA-b according to an embodiment illustrated in FIG. 11A is illustrated as including two curved surfaces respectively bent from two sides of the flat surface defined by the first direction axis DR1 and the second direction axis DR2. However, this is an example, and the shape of the display region F-Ab is not limited thereto. For example, the display region F-Ab may include only the flat surface defined by the first direction axis DR1 and the second direction axis DR2, or the display region F-Ab may further include at least two curved surfaces, for example, four curved surfaces respectively bent from four sides of the flat surface defined by the first direction axis DR1 and the second direction axis DR2.

The non-display region F-NAb may not be optically transparent and have a color. The non-display region F-NAb may be a region adjacent to the display region F-Ab. The non-display region F-NAb may surround the display region F-Ab.

The sub region MH-b may be disposed in the display region F-Ab. However, this is an example, and an arrangement of the sub region MH-b is not limited to thereto. For example, the sub region MH-b may be surrounded by the non-display region F-NAb, or surrounded by both the display region F-Ab and the non-display region F-NAb.

Referring to FIG. 11B, the electronic apparatus EA-b may include a second electronic module ELM, a display device DD-b, and a housing HAU. The display device DD-b may include a display module DM-b and a window member CW-b disposed on the display module DM-b. The display device DD-b may further include an optical layer OPL-b disposed between the display module DM-b and the window member CW-b. The optical layer OPL-b may include a polarization plate or a color filter layer. The display module DM-b may have a module region DM-MHb, and the second electronic module ELM may be disposed in a region corresponding to the module region DM-MHb.

In an embodiment, an electronic apparatus may include a display panel. The display panel according to an embodiment may include a reflection layer and a first electrode of a light-emitting element disposed on the reflection layer. The first electrode may be a transmissive electrode or a transflective electrode, and the light-emitting element may perform double-sided emission. In an embodiment, the display panel including a light-emitting element which performs double-side emission may have improved display quality by reducing color differences according to viewing angles. In addition, the display panel including the reflection layer may minimize loss of light. Accordingly, the display panel according to an embodiment and the electronic apparatus including the same may exhibit excellent display quality.

A display panel according to an embodiment and an electronic apparatus including the same may include a reflection layer disposed under a lower portion of a light-emitting element and thereby exhibit excellent display quality.

In the above, description has been made with reference to embodiments of the inventive concept, but those skilled in the art may appreciate that various modifications and changes may be made to the inventive concept insofar as such modifications and changes do not depart from the spirit and technical scope of the inventive concept set forth in the claims to be described later.

Therefore, the technical scope of the inventive concept is not to be limited to the contents stated in the detailed description of the specification, but should be determined by the claims.

What is claimed is:

1. A display panel comprising:
a base layer;
a first insulation layer disposed on the base layer and including a first opening;
a reflection layer disposed on the first insulation layer;
a second insulation layer disposed on the reflection layer;
a pixel-defining film disposed on the second insulation layer and including a second opening;
a first electrode disposed on the second insulation layer;
a light-emitting layer disposed on the first electrode and overlapping the first electrode in the second opening of the pixel-defining film; and
a second electrode disposed on the light-emitting layer,
wherein the first electrode includes a first part disposed in the first opening and arranged perpendicular to a thickness direction, and a second part extending from the first part and disposed on an inner surface of the first insulation layer which defines the first opening, and
the second part of the first electrode is inclined at a first acute angle of less than about 50° with respect to a plane perpendicular to the thickness direction.

2. The display panel of claim 1, wherein the first electrode includes a transmissive electrode or a transflective electrode.

3. The display panel of claim 1, wherein the reflection layer comprises a first part disposed in the first opening and overlapping the first part of the first electrode, and a second part extending from the first part of the reflection layer and disposed on the inner surface of the first insulation layer, and
the second part of the reflection layer is inclined at a second acute angle of less than about 50° with respect to the plane.

4. The display panel of claim 3, wherein the second acute angle satisfies the following Equation 1:
$${A}_{2} \leq ( 50 + {A}_{1} ) / 2 , \qquad [ Equation 1 ]$$
wherein, in the Expression 1, A₁ represents the first acute angle, and A₂ represents the second acute angle.

5. The display panel of claim 3, wherein the first part of the reflection layer extends in a first direction perpendicular to the thickness direction.

6. The display panel of claim 3, wherein the first part of the reflection layer is inclined at a third acute angle of less than about 25° with respect to the plane.

7. The display panel of claim 6, further comprising a third insulation layer disposed between the base layer and the first insulation layer,
wherein an upper surface of the third insulation layer disposed under the first insulation layer is not flat.

8. The display panel of claim 3, wherein, in a first direction perpendicular to the thickness direction, the second insulation layer is disposed between the second part of the reflection layer and the second part of the first electrode.

9. The display panel of claim 3, wherein the second part of the reflection layer does not overlap the first part of the first electrode.

10. The display panel of claim 1, wherein the reflection layer is provided in plurality, and
the plurality of reflection layers are spaced apart from each other in a first direction perpendicular to the thickness direction.

11. The display panel of claim 1, wherein the reflection layer comprises at least one of Ag, Mg, Cu, Al, Pt, Pd, Au, Ni, Nd, Ir, Cr, Li, Ca, Mo, Ti, or W.

12. The display panel of claim 1, wherein the first opening overlaps the second opening.

13. The display panel of claim 1, wherein each of the first insulation layer and the second insulation layer comprises an organic material.

14. The display panel of claim 1, wherein the display panel is foldable with respect to a folding axis.

15. An electronic apparatus comprising:
a display panel; and
a housing for accommodating the display panel,
wherein the display panel includes:
a base layer;
a first insulation layer disposed on the base layer and including a first opening;
a reflection layer disposed on the first insulation layer;
a second insulation layer disposed on the reflection layer;
a pixel-defining film disposed on the second insulation layer and including a second opening;
a first electrode disposed on the second insulation layer;
a light-emitting layer disposed on the first electrode and overlapping the first electrode in the second opening of the pixel-defining film; and
a second electrode disposed on the light-emitting layer,
wherein the first electrode includes a first part disposed in the first opening and arranged perpendicular to a thickness direction, and a second part extending from the first part and disposed on an inner surface of the first insulation layer which defines the first opening, and
the second part of the first electrode is inclined at a first acute angle of less than about 50° with respect to a plane perpendicular to the thickness direction.

16. The electronic apparatus of claim 15, wherein the first electrode includes a transmissive electrode or a transflective electrode.

17. The electronic apparatus of claim 15, wherein the reflection layer comprises a first part disposed in the first opening and overlapping the first part of the first electrode, and a second part extending from the first part of the reflection layer and disposed on the inner surface of the first insulation layer, and
the second part of the reflection layer is inclined at a second acute angle of less than about 50° with respect to the plane.

18. The electronic apparatus of claim 17, wherein the first part of the reflection layer extends in a first direction perpendicular to the thickness direction.

19. The electronic apparatus of claim 17, wherein the first part of the reflection layer is inclined at a third acute angle of less than about 25° with respect to the plane.

20. The electronic apparatus of claim 17, wherein the second part of the reflection layer does not overlap the first part of the first electrode.
